(19) United States
(12) Patent Application Publication
(10) Pub. No.: US 2025/0239690 A1
(43) Pub. Date: Jul. 24, 2025

(54) BATTERY PACK

(71) Applicant: Samsung SDI Co., Ltd., Yongin-si (KR)

(72) Inventors: Kyunghoon Park, Yongin-si (KR); Junhwa Park, Yongin-si (KR)

(21) Appl. No.: 18/778,308

(22) Filed: Jul. 19, 2024

(30) Foreign Application Priority Data
Jan. 18, 2024 (KR) 10-2024-0008296

(51) Int. Cl. H01M 10/6571; B60L 50/60; H01M 10/42; H01M 10/615; H01M 10/625; H01M 10/653; H01M 50/204; H01M 50/289

(52) U.S. Cl. CPC H01M 10/6571; H01M 10/425; H01M 10/615; H01M 10/625; H01M 10/653; H01M 50/204; H01M 50/289; B60L 50/60; H01M 2220/20

(57) ABSTRACT

A battery pack includes: a plurality of battery modules; and a power control device configured to control power supplied by the plurality of battery modules. The power control device includes: a case including a partition wall defining a seating region; an electrical element within the case; and a heat transfer element in contact with or applied around the electrical element.

### CROSS-REFERENCE TO RELATED APPLICATION

The present application claims priority to and the benefit of Korean Patent Application No. 10-2024-0008296, filed on Jan. 18, 2024, in the Korean Intellectual Property Office, the entire disclosure of which is incorporated herein by reference.

### BACKGROUND

### 1. Field

Aspects of embodiments of the present disclosure relate to a battery pack.

### 2. Description of the Related Art

Secondary batteries are designed to be chargeable and dischargeable and may be used as energy sources for mobile devices, electric vehicles, hybrid vehicles, electric bicycles, and uninterruptible power supplies. Depending on the type of external device to which the secondary battery is applied (e.g., powers), secondary batteries may be used in the form of a single battery cell or in the form of a module or pack in which multiple battery cells are connected together and bundled into one unit.

The information disclosed in this Background section is to facilitate the understanding of the background of the present disclosure, and therefore, it may include information that does not constitute prior art.

### SUMMARY

Embodiments of the present disclosure include a battery pack exhibiting increased heat dissipation performance of a power control device without an increase in the specifications and/or sizes of electrical elements included in the power control device.

However, the aspects and features of the present disclosure are not limited to those mentioned above, and other aspects and features not mentioned may be clearly understood by those skilled in the art from the description of the present disclosure described below.

Additional aspects and features will be set forth, in part, in the description that follows and, in part, will be apparent from the description or may be learned by practice of the presented embodiments of the present disclosure.

According to an embodiment of the present disclosure, a battery pack includes a plurality of battery modules and a power control device configured to control power of the plurality of battery modules. The power control device includes a case including a partition wall defining a seating region, an electrical element within the case, and a heat transfer element in contact with or applied around the electrical element.

The electrical element and the heat transfer element may be in the seating region.

The heat transfer element may be in contact with the partition wall and the electrical element.

The heat transfer element may be in contact with a plurality of surfaces of the electrical element.

The seating region, the electrical element, and the heat transfer element may each be provided in plurality in the case, and the plurality of seating regions may be spaced apart from each other.

The case may have a first surface forming a bottom surface of the case and a second surface extending along an edge of the first surface.

The partition wall may include an inner partition wall extending from the first surface and spaced apart from the second surface and an outer partition wall extending from the second surface toward the inner partition wall.

The heat transfer element applied within the inner partition wall may be in contact with the inner partition wall and one surface of the electrical element.

The outer partition wall may include two outer partition walls spaced apart from the second surface and between which the heat transfer element is applied.

The seating region, the electrical element, the heat transfer element, and the partition wall may each be provided in plurality.

The seating region may include a first seating region, a second seating region, and a third seating region spaced apart from each other.

The first partition wall may include a first inner partition wall extending upwardly from the first surface and having both ends extending in a longitudinal direction toward the second surface and two first outer partition walls extending from the second surface toward the first inner partition wall and being spaced apart from each other.

The first heat transfer element may include a first inner heat transfer element accommodated in the first inner partition wall and in contact with one surface of the first electrical element.

The second partition wall may include a second inner partition wall extending upwardly from the first surface, both ends of which extend in the longitudinal direction toward the second surface, and two second outer partition walls extending from the second surface toward the second inner partition wall and spaced apart from each other.

The second electrical element may have an outer circumferential surface that is at least partially curved, and a portion of the second heat transfer element may have a concave shape corresponding to the outer circumferential surface of the second electrical element.

The case may have a third surface protruding upwardly from the first surface and a groove around the third surface.

The third partition wall may include a third inner partition wall extending upwardly from the first surface, both ends of which extend in the longitudinal direction toward the second surface, and two third outer partition walls extending from the second surface toward the third inner partition wall and spaced apart from each other.

The third heat transfer element may include a third inner heat transfer element accommodated in the third inner partition wall and in contact with one surface of the third electrical element.

The first electrical element may be a minus main relay, the second electrical element may be a fuse, and the third electrical element may be a plus main relay.

The heat transfer element may include a binder and a thermally conductive inorganic filler mixture.

### BRIEF DESCRIPTION OF THE DRAWINGS

The above and other aspects and features of the present disclosure will be more apparent from the following description taken in conjunction with the accompanying drawings, in which:

FIG. 1 is a diagram showing a vehicle including a battery pack according to embodiments;

FIG. 2 is a diagram schematically showing a battery pack according to embodiments;

FIG. 3 is a perspective view of a power control device;

FIG. 4 is a diagram showing an interior of the power control device shown in FIG. 3;

FIG. 5 is a diagram showing a state in which electrical elements shown in FIG. 4 are removed;

FIG. 6 is a cross-sectional view taken along the line A-A′ in FIG. 4;

FIG. 7 is a cross-sectional view taken along the line B-B′ in FIG. 4; and

FIG. 8 is a cross-sectional view taken along the line C-C′ in FIG. 4.

### DETAILED DESCRIPTION

Reference will now be made, in detail, to embodiments, examples of which are illustrated in the accompanying drawings. The present embodiments, and the present disclosure, may have different forms and should not be construed as being limited to the descriptions or embodiments set forth herein. Accordingly, embodiments are merely described below, by referring to the figures, to explain aspects and features of the present description.

Some embodiments of the present disclosure and methods according thereto may be understood by referring to the detailed descriptions and drawings of the embodiments. The described embodiments may have various modifications and may be implemented in different forms and are not limited to the following descriptions. Additionally, some or all of the aspects and features of various embodiments of the present disclosure may be combined with each other. Each embodiment may be implemented independently or in connection with each other.

The described embodiments are provided as examples so that the present disclosure is thorough and complete and are also intended to convey the spirit of the present disclosure to those skilled in the art to which the present disclosure pertains. The present disclosure includes all modifications, equivalents, and substitutions within the spirit and technical scope of the present disclosure. Accordingly, processes, elements, and techniques that are not necessary for those skilled in the art to have a complete understanding of the present disclosure may not be described or may be only briefly described.

Unless otherwise noted throughout the accompanying drawings and specification, like reference numerals, letters, or combinations thereof indicate the same components and, thus, overlapping descriptions are omitted. Additionally, to clearly explain aspects and features of the present disclosure, parts not related to the description or parts unrelated to the description may be omitted or only briefly described.

The relative sizes of elements, layers, and regions in the drawings may be exaggerated for clarity. The use of hatching and/or shading in the accompanying drawings are provided to clarify boundaries between generally adjacent elements. Accordingly, the presence or absence of hatching or shading does not indicate a particular material, material properties, dimensions, proportions, commonality between figure elements, and/or other characteristics or properties of one element that is not designated, desirable form, or requirements for attributes, etc.

Various embodiments are described in the present disclosure with reference to cross-sectional examples, which are schematic illustrations of embodiments and/or intermediate structures. The appearance of the drawing may therefore vary, for example, as a result of manufacturing techniques and/or tolerances. In addition, the specific structural or functional description in the specification is merely an example for explaining embodiments of the present disclosure. Accordingly, the embodiments disclosed in this specification should not be construed as being limited to the shape of the illustrated area and include, for example, deviation in shape due to manufacturing.

Areas shown in the drawings are schematic in nature and their shapes are not intended to be limiting or illustrative of the actual shape of the device areas. Additionally, as those skilled in the art will recognize, the described embodiments may be modified in various ways without departing from the spirit or scope of the present disclosure.

Numerous specific details are set forth in the specification to provide a thorough understanding of the various embodiments. However, various embodiments may be practiced without or including one or more of these specific details. In other instances, well-known structures and devices are shown in block diagram form to avoid unnecessarily obscuring the various embodiments.

As illustrated in the drawings, to more easily describe a relationship between one element or feature to another element or feature, spatially relative terms, such as “below”, “above”, “lower”, “upper”, etc., may be used. Spatially relative terms are intended to include various orientations of a device in use or operation in addition to those shown in the drawings. For example, if the device in the drawings is turned over, other elements or features described as “below” or “lower” may face “above” the other elements or features. Accordingly, as illustrative terms, “down” and “lower” may include both up and down directions. A device may be oriented in different directions (e.g., rotated 90 degrees or in other directions) and the spatially relative descriptions used in the present disclosure should be interpreted accordingly. Similarly, if a first part is described as being disposed “above” a second part, this denotes that the first part is disposed above or below the second part.

In addition, the expression “viewed from a plane” refers to a view of an object from above, and the expression “in a schematic cross-section view” refers to a schematic cross-section taken by cutting the object vertically. The term “viewed from a side” denotes that a first object may be above, below, or to a side of a second object and vice versa. Additionally, the terms “overlap” or “doubled” may include layer, stack, surface, extension, covering, or partially covering, or any other suitable term that would be understood by one of ordinary skill in the art. The expression “does not overlap” may include meanings such as “spaced apart from,” “separated from,” “offset from,” and any other suitable equivalents recognized and understood by those skilled in the art. The terms “face” and “surface” may denote that a first object may directly or indirectly face a second object. If there is a third object between the first object and the second object, the first object and the second object face each other, but may be understood as indirectly facing each other.

If an element, layer, region, or component is referred to as being “formed,” “connected,” or “coupled” to another element, it may be said to be formed directly on a layer, region, or component, formed on another component, layer, region or component, or indirectly formed on, connected to, or coupled to another component. It also may be collectively referred to direct or indirect combinations or connections of elements, layers, regions, or components and integral or non-integral combinations or connections so that one or more elements, layers, regions, or components may be present. For example, if an element, layer, region, or component is referred to as being “electrically connected” or “electrically coupled” to another element, layer, region, or component, this means that the element, layer, region, or component may be directly electrically connected or coupled, or other elements, layers, regions, or components may be present. However, “direct connection” or “direct coupling” means that one component is directly connected or combined with another component without an intermediate component or exits on another component. Additionally, in the present specification, if a part of a layer, film, region, plate, etc. is formed in another part, the formation direction is not limited to an upper direction and includes that the part is formed on a side or bottom. Conversely, if a part of a layer, film, region, plate, etc. is formed “under” another part, it includes not only a case in which the part is “immediately below” the other part, but also a case in which another part is present between the part and the other part. Meanwhile, other expressions that describe relationships between components, such as “between,” “immediately between,” “adjacent to,” and “immediately adjacent to,” may be interpreted similarly. Additionally, if an element or layer is referred to as being “between” two elements or layers, it may be an only element between the two elements or layers, or there may be other elements in therebetween.

Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

Although the terms “first”, “second”, “third”, etc. may be used herein to describe various elements, components, regions, layers, and/or sections, such elements, components, regions, layers, and/or cross-section are not limited by these terms. These terms are used to distinguish one element, component, region, layer, or cross-section from another element, component, region, layer, or cross-section. Accordingly, a first element, component, region, layer, or cross section described below may be referred to as a second element, component, region, layer, or cross section without departing from the spirit and scope of the present disclosure. Describing an element as a “first” element may not require or imply the presence of a second or another element. Terms such as “first,” “second,” etc. may be used herein to distinguish different categories or sets of elements in the present disclosure. For clarity, terms such as “first,” “second,” etc. may refer to “first category (or first set),” “second category (or second set),” etc., respectively.

The terms used in this application are only used to describe specific embodiments and are not intended to limit the present disclosure. As used herein, singular terms are intended to include plural terms and plural terms are also intended to include the singular, unless the context clearly dictates otherwise. The terms “include,” “provide,” and “have” if used herein are meant to designate the presence of specified features, integers, or operations. These expressions do not exclude the presence or addition of one or more other functions, steps, operations, components, and/or groups thereof.

If one or more embodiments may be implemented differently, a certain process sequence may be performed differently than a described order. For example, two processes described in succession may be performed substantially simultaneously or may be performed in an order opposite to that described.

As used herein, the terms “substantially,” “about,” and similar terms are used in terms of approximation and not in terms of degree and are intended to account for inherent variations in measured or calculated values that would be recognized by a person of ordinary skill in the art. As used herein, the term “about” or “approximately” includes the stated value and denotes within a permissible range of deviation (e.g., a range of deviation due to limitations of the measurement system) for a specific value as determined by an ordinary skill in the art taking into account the corresponding measurement and associated errors. For example, the term “about” may denote within one or more standard deviations or within ±30%, 20%, 10%, or 5% of a specified value.

Unless otherwise defined, all terms used herein, including technical or scientific terms, have the same meaning as commonly understood by an ordinary skill in the technical field to which the present disclosure belongs. Terms, such as those defined in commonly used dictionaries shall be construed to have a meaning consistent with their meaning in the context of the relevant technology and/or this specification, and unless explicitly defined herein, it is not to be interpreted in an idealized or overly formal sense.

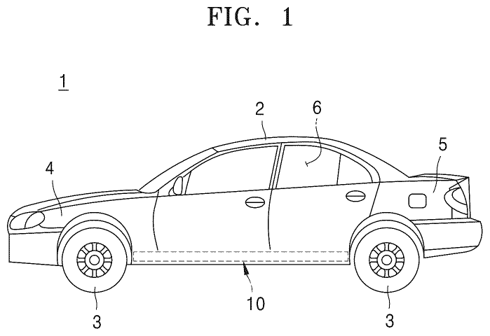

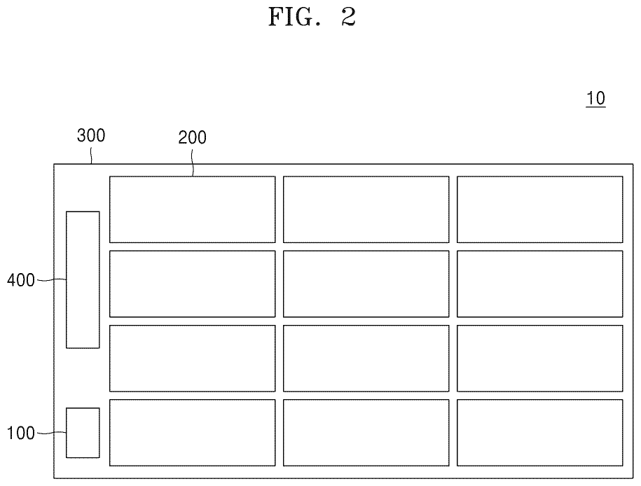

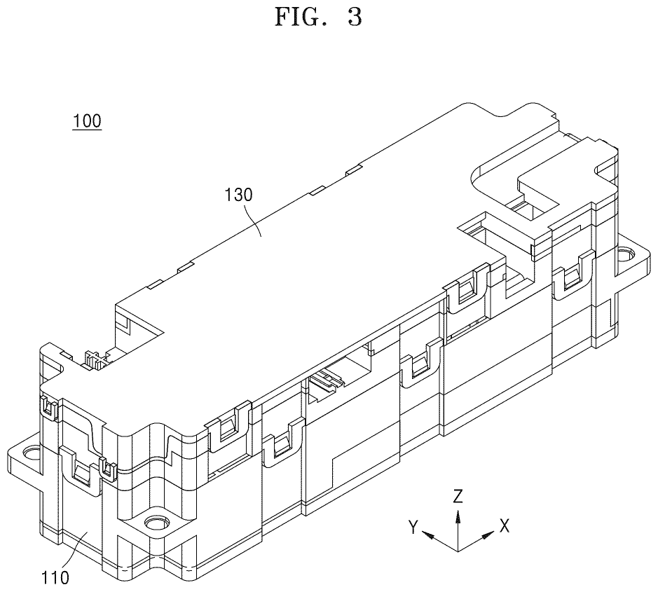

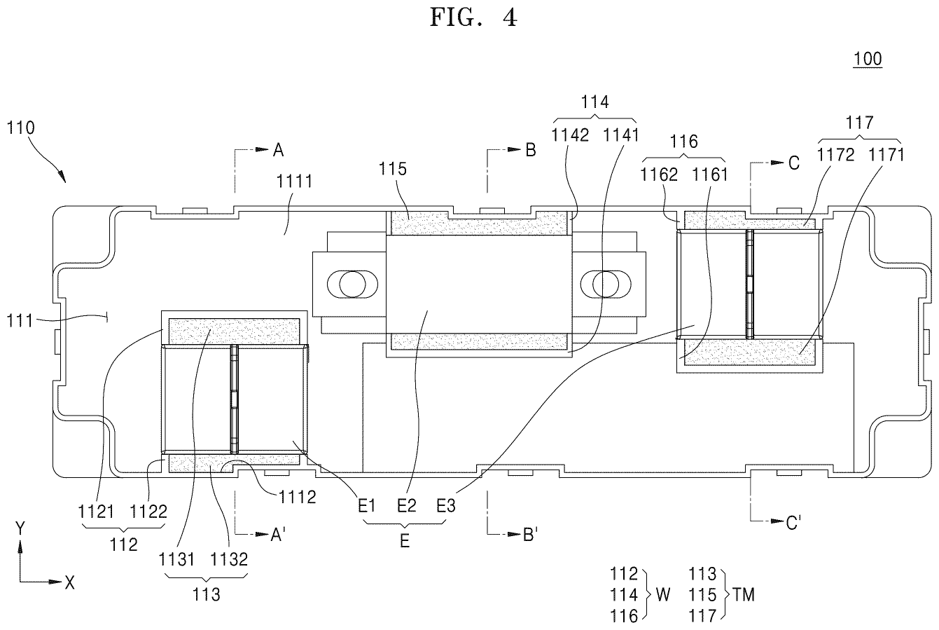

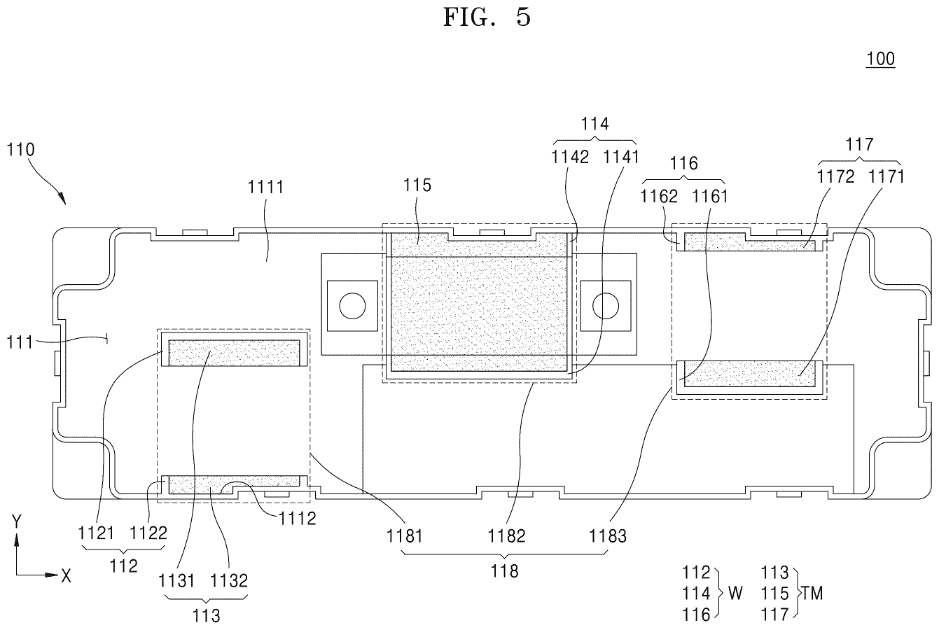

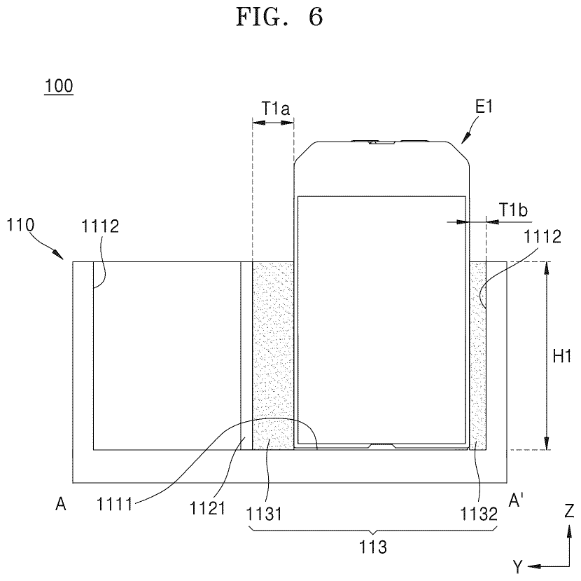

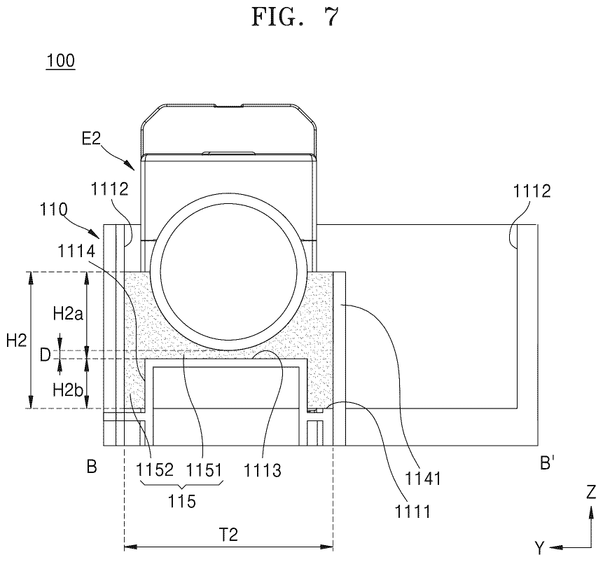

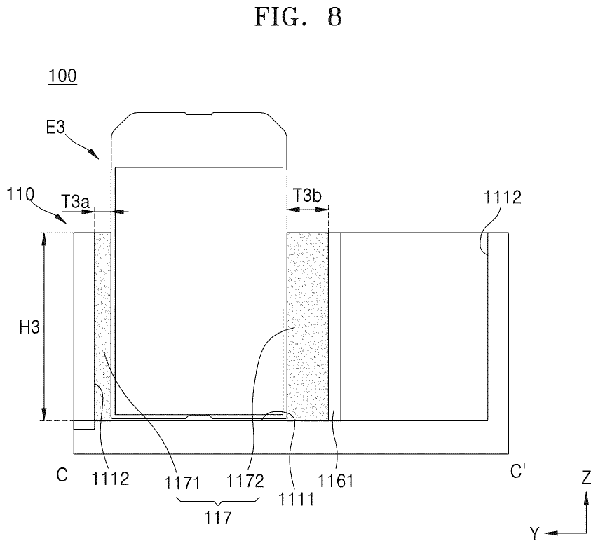

FIG. 1 is a diagram showing a vehicle 1 including a battery pack 10, FIG. 2 is a diagram schematically showing the battery pack 10, FIG. 3 is a perspective view of a power control device 100 of the battery pack 10, FIG. 4 is a diagram showing an interior of the power control device 100 shown in FIG. 3, FIG. 5 is a diagram showing a state in which electrical elements E shown in FIG. 4 are removed, FIG. 6 is a cross-sectional view taken along the line A-A′ in FIG. 4, FIG. 7 is a cross-sectional view taken along the line B-B′ in FIG. 4, and FIG. 8 is a cross-sectional view taken along the line C-C′ in FIG. 4.

The battery pack 10 may be mounted on (or to) the vehicle 1. The vehicle 1 may be an electric vehicle, a hybrid vehicle, or a plug-in hybrid vehicle. The vehicle 1 may be a four-wheeled vehicle, a two-wheeled vehicle, etc. As shown in FIG. 1, the battery pack 10 may be located inside (e.g., within) a frame 2 of the vehicle 1, for example, between a front end 4 and the rear end 5 of the vehicle 1. For example, the battery pack 10 may be located between a front wheel 3 and a rear wheel 3 and below an interior space 6 where passengers sit. The battery pack 10 may be applied to applications other than the vehicle 1. For example, the battery pack 10 may be applied to large applications, such as an energy storage system (ESS) or electronic devices, such as power tools.

The battery pack 10 includes a plurality of battery modules 200 and a power control device 100 configured to control power of the plurality of battery modules 200. The power control device 100 includes a partition wall W, a case 110 including a seating region (e.g., an accommodation space) 118 defined by the partition wall W, an electrical element E within the case 110, and a heat transfer element TM in contact with the electrical element E or applied around the electrical element E.

The battery pack 10 may include the power control device 100, the battery modules 200, a housing 300, and a controller 400.

The power control device 100 is located within the housing 300 and may control the power of the battery pack 10. The power control device 100 is electrically connected to the battery modules 200 and is controlled by the controller 400 to receive power supplied from the battery modules 200 and to deliver the power to loads (e.g., motor, inverter, etc.). The power control device 100 not only supplies power to the loads but is also controlled by the controller 400 to cut off power supplied from (or supplied by) the battery modules 200 to the loads if a problem, such as overcurrent, overvoltage, leakage, or a short circuit, occurs in the battery modules 200. For example, the power control device 100 may include a power relay assembly (PRA). The power control device 100 may be located at one end of housing 300.

The power control device 100 may include an electrical element E, the case 110, and a cover 130.

One or more electrical elements E may be included in the power control device 100 and may control a current supplied from the battery modules 200 to an application (e.g., a load), such as the vehicle 1, through the power control device 100. The electrical element E may include a relay and a fuse. The electrical element E may include a first electrical element E1, a second electrical element E2, and a third electrical element E3, and the three electrical elements E1-E3 may include a minus (or negative) main relay, a fuse, and a plus (or positive) main relay. For example, the first electrical element E1 may include a plus main relay, the second electrical element E2 may include a fuse, and the third electrical element E3 may include a minus main relay. The electrical element E may be within the case 110 and may be in contact with or near the heat transfer element TM. Heat generated by the electrical element E while it is operating is effectively dissipated through the heat transfer element TM, thereby preventing the electrical element E from overheating. The plurality of electrical elements E may be spaced apart from each other. For example, each electrical element E is in an internal space 111 of the case 110 and may be in the seating region 118 defined by a first surface 1111 and a second surface 1112 of the internal space 111. The electrical element E may be within the seating region 118 along with the heat transfer element TM.

The case 110 may hold (e.g., may accommodate) and support the electrical element E. The case 110 may form a space in which the electrical element E and the heat transfer element TM are accommodated. The case 110 may form a lower frame of the power control device 100 and may include a bottom surface on which the electrical element E and the heat transfer element TM are placed.

The case 110 may have the internal space 111, the seating region 118, the partition wall W, and the heat transfer element TM. The seating region 118, the electrical element E, the heat transfer element TM, and the partition wall W may respectively include a plurality of seating regions 118, a plurality of electrical elements E, a plurality of heat transfer elements TM, a plurality of the partition walls W.

The internal space 111 may be a space in which other components of the case 110 (e.g., the seating region 118, the partition wall W, and the heat transfer element TM) and the electrical element E are formed or located. The internal space 111 may be defined by the case 110.

The internal space 111 may have (or may be formed between) the first surface 1111 and the second surface 1112.

For example, as shown in FIG. 4, the first surface 1111 includes a bottom surface of the internal space 111, and the second surface 1112 may extend along (or may extend from) an edge of the first surface 1111. The first surface 1111 may be a flat surface parallel to a floor or a surface of a region at where the power control device 100 is installed. An electrical element E and a heat transfer element TM may be on the first surface 1111.

The internal space 111 may further have (or may be further formed between) a third surface 1113 and a groove 1114.

The third surface 1113 and the groove 1114 may be formed in the internal space 111 to correspond to the electrical element E and the heat transfer element TM.

The third surface 1113 may protrude upwardly from the first surface 1111 to form a step difference with the first surface 1111. The groove 1114 may be formed between the third surface 1113 and the first surface 1111 around the third surface 1113. For example, a portion of the heat transfer element TM on the third surface 1113 may be in (e.g., may be inserted into) the groove 1114 and may be supported by the first surface 1111, the second surface 1112, and the partition wall W. For example, the third surface 1113 and the groove 1114 may be formed to correspond to a second seating region 1182.

For example, as shown in FIG. 7, the third surface 1113 may be formed to correspond to the second electrical element E2 and a second heat transfer element 115. The third surface 1113 may protrude upwardly toward the second electrical element E2 to form a step difference with the peripheral first surface 1111. Also, the grooves 1114 may be formed at both sides of the third surface 1113, for example, at a side facing a second inner partition wall 1141 and at a side facing the second surface 1112. The third surface 1113 is spaced apart from the second electrical element E2 by a distance D, and a second inner heat transfer element 1151 of the second heat transfer element 115 may be between the third surface 1113 and the second electrical element E2. A second outer heat transfer element 1152 extending downwardly from the second inner heat transfer element 1151 may be in (e.g., may be inserted into) the grooves 1114.

The seating region 118 is a region where the electrical element E is seated, and there may be a heat transfer element TM inside or around the seating region 118. One or more seating regions 118 may be defined in the internal space 111, and each seating region 118 may have at least one electrical element E thereon. For example, the number of seating regions 118 may be the same as the number of electrical elements E and, in some embodiments, may be three. For example, the seating region 118 may include a first seating region 1181, a second seating region 1182, and a third seating region 1183 corresponding to the first electrical element E1, the second electrical element E2, and the third electrical element E3, respectively.

The seating region 118 is defined by a partition wall W formed on the first surface 1111 and the second surface 1112, and the electrical element E may be in the seating region 118. For example, the seating region 118 may be defined as an inner region of the first surface 1111, the second surface 1112, and the partition wall W. The electrical element E is seated in the seating region 118 and the heat transfer element TM is applied around the electrical element E and may surround or at least partially surround the electrical element E. The electrical element E and the heat transfer element TM are each in the seating region 118 and may not deviate to (or may not extend to) the outside of the seating region 118. Each seating region 118 may be distinguished and spaced apart from each other. For example, the seating region 118 may be a region formed by extending the first surface 1111, the second surface 1112, and the outer edge of the partition wall W.

The first electrical element E1 and a first heat transfer element 113 may be in the first seating region 1181. For example, as shown in FIG. 5, the first seating region 1181 may be defined by the first surface 1111, the second surface 1112, and the first partition wall 112. The first electrical element E1 may be a plus main relay, and the first heat transfer element 113 may be applied to both sides of the first electrical element E1 in a width direction of the power control device 100 (e.g., the Y-axis direction in FIG. 5). For example, a first inner partition wall 1121 extends from the first surface 1111 in a height direction of the power control device 100 (e.g., a Z-axis direction in FIG. 3), and a first outer partition wall 1122 may extend from the second surface 1112 toward the internal space 111 in the width direction of the power control device 100. The two first outer partition walls 1122 may be spaced apart in a longitudinal direction of the power control device 100 (e.g., the X-axis direction in FIG. 5) and may extend from the second surface 1112, respectively. The first inner partition wall 1121 and the first outer partition wall 1122 may be spaced apart from each other in the width direction of the power control device 100 (e.g., a Z-axis direction in FIG. 5). For example, the first seating region 1181 is formed toward one side of the power control device 100 (e.g., the left side in FIG. 5) and may be spaced apart from the second seating region 1182 and the third seating region 1183.

The first seating region 1181 may be defined by the first inner partition wall 1121, the first outer partition wall 1122, and the first surface 1111 and the second surface 1112 corresponding to the first inner partition wall 1121 and the first outer partition wall 1122. The first electrical element E1 may be at the center of the first seating region 1181, and a first inner heat transfer element 1131 may be accommodated in the first inner partition wall 1121 to be in contact with one side of the first electrical element E1 and the first inner partition wall 1121. Also, a first outer heat transfer element 1132 may be accommodated in the first outer partition wall 1122 to be in contact with the other side of the first electrical element E1 and the first outer partition wall 1122, respectively.

Heat emitted from the first electrical element E1 is absorbed by the first inner heat transfer element 1131 and the first outer heat transfer element 1132, respectively, and may be discharged to the outside of the power control device 100 through the first surface 1111, the second surface 1112, the first inner partition wall 1121, and the first outer partition wall 1122.

The second electrical element E2 and the second heat transfer element 115 may be in the second seating region 1182. For example, the second seating region 1182 may be defined by the first surface 1111, the second surface 1112, the third surface 1113, the groove 1114, and the second partition wall 114. The second electrical element E2 may be a fuse, and the second heat transfer element 115 may be applied to both sides and a bottom of the second electrical element E2 in the width direction (e.g., the Y-axis direction in FIG. 5) of the power control device 100. For example, the second inner partition wall 1141 may extend from the first surface 1111 in the height direction of the power control device 100 (e.g., the Z-axis direction in FIG. 3), and a second outer partition wall 1142 may extend from the second surface 1112 toward the internal space 111 in the width direction of the power control device 100. The two second outer partition walls 1142 spaced apart in the longitudinal direction of the power control device 100 (e.g., the X-axis direction in FIG. 5), may extend from the second surface 1112, respectively. The second inner partition wall 1141 and the second outer partition wall 1142 may be spaced apart from each other in the width direction of the power control device 100 (e.g., a Z-axis direction in FIG. 5). For example, the second seating region 1182 is formed at the center of the power control device 100 and may be spaced apart from the first seating region 1181 and the third seating region 1183.

The second seating region 1182 may be defined by the second inner partition wall 1141, the second outer partition wall 1142, and the first surface 1111, the second surface 1112, the third surface 1113, and the groove 1114 corresponding to the second inner partition wall 1141 and the second outer partition wall 1142. The second electrical element E2 may be at the center of the second seating region 1182, and the second inner heat transfer element 1151 is below the second electrical element E2 and at the center of the second seating region 1182. For example, the second inner heat transfer element 1151 may be between the third surface 1113 and the second electrical element E2. The second inner heat transfer element 1151 may be in contact with the second inner partition wall 1141 and the second outer partition wall 1142, respectively, while surrounding at least a portion of the second electrical element E2. The second outer heat transfer element 1152 may extend from the second inner heat transfer element 1151 and may be respectively inserted into the grooves 1114.

Heat emitted from the second electrical element E2 is absorbed by the second inner heat transfer element 1151 and the second outer heat transfer element 1152, respectively, and may be discharged to the outside of the power control device 100 through the first surface 1111, the second surface 1112, the third surface 1113, the groove 1114, the second inner partition wall 1141, and the second outer partition wall 1142.

The third seating region 1183 may include the third electrical element E3 and a third heat transfer element 117. For example, as shown in FIG. 5, the third seating region 1183 may be defined by the first surface 1111, the second surface 1112, and the first partition wall 112. The third electrical element E3 may be a minus main relay, and the third heat transfer element 117 may be applied to both sides of the third electrical element E3 in the width direction of the power control device 100 (e.g., the Y-axis direction in FIG. 5). For example, a third inner partition wall 1161 may extend from the first surface 1111 in the height direction of the power control device 100 (e.g., the Z-axis direction in FIG. 3), and a third outer partition wall 1162 may extend from the second surface 1112 toward the internal space 111 in the width direction of the power control device 100. The two third outer partition walls 1162 spaced apart in the longitudinal direction of the power control device 100 (e.g., the X-axis direction in FIG. 5), may extend from the second surface 1112, respectively. The third inner partition wall 1161 and the third outer partition wall 1162 may be spaced apart from each other in the width direction of the power control device 100 (e.g., a Z-axis direction in FIG. 5). For example, the third seating region 1183 is formed toward the other side of the power control device 100 (e.g., the right side in FIG. 5) and may be spaced apart from the first seating region 1181 and the second seating region 1182.

The third seating region 1183 may be defined by the third inner partition wall 1161, the third outer partition wall 1162, and the first surface 1111 and the second surface 1112 corresponding to the third inner partition wall 1161 and the third outer partition wall 1162. The third electrical element E3 may be at the center of the third seating region 1183, and a third inner heat transfer element 1171 may be accommodated in the third inner partition wall 1161 to be in contact with one side of the third electrical element E3 and the third inner partition wall 1161, respectively. Also, a third outer heat transfer element 1172 may be accommodated in the third outer partition wall 1162 to be in contact with the other side of the third electrical element E3 and the third outer partition wall 1162, respectively.

Heat emitted from the third electrical element E3 is absorbed by the third inner heat transfer element 1171 and the third outer heat transfer element 1172, respectively, and may be discharged to the outside of the power control device 100 through the first surface 1111, the second surface 1112, the third inner partition wall 1161, and the third outer partition wall 1162.

The partition walls W may define the seating region 118 where the electrical element E and the heat transfer element TM are located. The partition walls W may support the electrical element E and the heat transfer element TM so that the electrical element E and the heat transfer element TM do not leave (or migrate) from the seating region 118. One or more partition walls W may be formed in the case 110. For example, the partition walls W may extend in one or more of the longitudinal direction, width direction, and height direction of the power control device 100 from the first surface 1111 and the second surface 1112. The partition walls W may extend from one or more of the first surface 1111 and the second surface 1112. One or more partition walls W may be formed in each seating region 118. The partition walls W may have a height less than or equal to a height of the case 110 (e.g., a height of the second surface 1112). The partition walls W may have a height greater than or equal to the height of the heat transfer element TM.

The partition walls W may regulate a region where the heat transfer element TM is applied and a size and shape of the applied heat transfer element TM. For example, the electrical element E may be in one of the seating regions 118 and the heat transfer element TM may be applied around it. The applied heat transfer element TM may not flow to another region of the internal space 111 or to another seating region 118 due to the electrical element E and the partition walls W. Also, a thickness, height, and shape of the heat transfer element TM may be adjusted as desired by the partition walls W.

The partition wall W may include an inner partition wall extending from the first surface 1111 and spaced apart from the second surface 1112 and an outer partition wall extending from the second surface 1112 toward the inner partition wall. For example, the inner partition wall may include the first inner partition wall 1121, the second inner partition wall 1141, and the third inner partition wall 1161, which will be described in more detail below. For example, the outer partition wall may include the first outer partition wall 1122, the second outer partition wall 1142, and the third outer partition wall 1162, which will be described in more detail below. The outer partition wall may include two outer partition walls spaced apart from each other on the second surface 1112 between which the heat transfer element TM is applied.

The heat transfer elements TM applied to the inner partition wall (e.g., the first inner heat transfer element 1131, the second inner heat transfer element 1151, and the third inner heat transfer element 1171, described below) may be in contact with one surface of the inner partition wall and the electrical element E. The heat transfer elements TM applied to an inside of the outer partition wall (e.g., the first outer heat transfer element 1132, the second outer heat transfer element 1152, and the third outer heat transfer element 1172, which are described below) may be in contact with the outer partition wall, the second surface 1112, and the other surface of the electrical element E.

The partition wall W may include the first partition wall 112, the second partition wall 114, and a third partition wall 116.

The first partition wall 112 may be formed to correspond to the first seating region 1181. The first partition wall 112 may support the first electrical element E1 and the first heat transfer element 113. For example, the first partition wall 112 may support the first electrical element E1 and the first heat transfer element 113 together with the first surface 1111 and the second surface 1112.

The first partition wall 112 may include the first inner partition wall 1121 and the first outer partition wall 1122.

The first inner partition wall 1121 may extend upwardly from the first surface 1111. For example, as shown in FIG. 4, the first inner partition wall 1121 is separated from the second surface 1112 and extends upwardly from the first surface 1111, and both ends thereof may extend towards the first outer partition wall 1122, respectively. For example, the first inner partition wall 1121 may have a long side extending in the longitudinal direction of the power control device 100 (e.g., the X-axis direction in FIG. 4) and two short sides, each extending in the width direction of the power control device 100 (e.g., the Y-axis direction in FIG. 4), for example, toward the first outer partition wall 1122 from both ends of the long side. The first inner partition wall 1121 may accommodate the first heat transfer element 113 (e.g., the first inner heat transfer element 1131) therein. Both ends of the first inner partition wall 1121 may contact one side surface of the first electrical element E1. In this regard, side surfaces of the first inner heat transfer element 1131 may be completely surrounded by the first electrical element E1 and the first inner partition wall 1121. A height of the first inner partition wall 1121 may be equal to or greater than the height of the first inner heat transfer element 1131.

The first outer partition wall 1122 may extend from the second surface 1112 toward the first inner partition wall 1121. The first outer partition wall 1122 may be formed continuously along an entire height direction of the second surface 1112 or may extend upwardly from a bottom of the first surface 1111 and may have a height less than the second surface 1112. A plurality of outer partition walls 1122 may be included. For example, as shown in FIG. 4, the two first outer partition walls 1122 may be spaced apart in the longitudinal direction of the power control device 100 (e.g., the X-axis direction in FIG. 4). The first outer heat transfer element 1132 of the first heat transfer element 113 may be inserted into a space between the two first outer partition walls 1122. Both ends of the first outer partition wall 1122 may contact the other side of the first electrical element E1. In this regard, side surfaces of the first outer heat transfer element 1132 may be completely surrounded by the first electrical element E1 and the first outer partition wall 1122. A height of the first outer partition wall 1122 may be equal to or greater than the height of the first outer heat transfer element 1132.

The second partition wall 114 may be formed to correspond to the second seating region 1182. The second partition wall 114 may support the second electrical element E2 and the second heat transfer element 115. For example, the second partition wall 114 may support the second electrical element E2 and the second heat transfer element 115 together with the first surface 1111, the second surface 1112, the third surface 1113, and the groove 1114.

The second partition wall 114 may include the second inner partition wall 1141 and the second outer partition wall 1142.

The second inner partition wall 1141 may extend upwardly from the first surface 1111. For example, as shown in FIG. 4, the second inner partition wall 1141 may extend upwardly from the first surface 1111, and both ends thereof may extend toward the second outer partition wall 1142, respectively. The second inner partition wall 1141 may accommodate the second heat transfer element 115 therein. For example, the second inner partition wall 1141 may have a first part extending in the longitudinal direction of the power control device 100 (e.g., the X-axis direction in FIG. 4) and two second parts extending in the width direction of the power control device 100 (e.g., the Y-axis direction in FIG. 4), for example, toward the second outer partition wall 1142 at both ends of the first part, respectively.

The second inner partition wall 1141 may have a shape corresponding to the shape of the second electrical element E2. For example, as shown in FIG. 7, when the second electrical element E2 includes a shape including an outer circumferential surface, at least a portion of which is curved (e.g., is a cylindrical coil), at least a portion of the second inner partition wall 1141 (e.g., the two second parts at both ends) may have a partially curved shape (e.g., a concave shape) to correspond to the second electrical element E2. Therefore, as shown in FIG. 4, both ends of the second electrical element E2 in the longitudinal direction may be seated or supported on both ends of the second inner partition wall 1141, respectively. A portion of the second inner partition wall 1141 that contacts the second electrical element E2 may have a height less than that of the other portion(s) of the second inner partition wall 1141.

The second outer partition wall 1142 may extend from the second surface 1112 toward the second inner partition wall 1141. The second outer partition wall 1142 may be formed continuously along the entire height direction of the second surface 1112 or may have a height less than that of the second surface 1112 by extending upwardly from the first surface 1111. A plurality of second outer partition walls 1142 may be included. For example, as shown in FIG. 4, the two second outer partition walls 1142 may be spaced apart in the longitudinal direction of the power control device 100 (e.g., the X-axis direction in FIG. 4). The second outer heat transfer element 1152 of the second heat transfer element 115 may be inserted into a space between the two second outer partition walls 1142. A height of the second outer partition wall 1142 may be equal to or greater than the height of the second outer heat transfer element 1152.

The second inner partition wall 1141 and the second outer partition wall 1142 may contact each other. For example, as shown in FIG. 5, both ends of the second inner partition wall 1141 may be in contact with the two second outer partition walls 1142, respectively. The second inner partition wall 1141 and the second outer partition wall 1142 may be formed integrally, that is, as one piece.

The third partition wall 116 may be formed to correspond to the third seating region 1183. The third partition wall 116 may support the third electrical element E3 and the third heat transfer element 117. For example, the third partition wall 116 may support the third electrical element E3 and the third heat transfer element 117 together with the first surface 1111 and the second surface 1112.

The third partition wall 116 may include a third inner partition wall 1161 and a third outer partition wall 1162.

The third inner partition wall 1161 may extend upwardly from the first surface 1111. For example, as shown in FIG. 4, the third inner partition wall 1161 is spaced apart from the second surface 1112 and extends upwardly from the first surface 1111, and both ends thereof may extend towards the third outer partition wall 1162, respectively. For example, the third inner partition wall 1161 may have a long side extending in the longitudinal direction of the power control device 100 (e.g., the X-axis direction in FIG. 4) and two short sides each extending in the width direction of the power control device 100 (e.g., the Y-axis direction in FIG. 4), for example, toward the third outer partition wall 1162 from both ends of the long side. The third inner partition wall 1161 may accommodate the third heat transfer element 117 (e.g., the third inner heat transfer element 1171) therein. Both ends of the third inner partition wall 1161 may contact one side surface of the third electrical element E3. In this regard, side surfaces of the third inner heat transfer element 1171 may be completely surrounded by the third electrical element E3 and the third inner partition wall 1161. A height of the third inner partition wall 1161 may be equal to or greater than the height of the third inner heat transfer element 1171.

The third outer partition wall 1162 may extend from the second surface 1112 toward the third inner partition wall 1161. The third outer partition wall 1162 may be formed continuously along an entire height direction of the second surface 1112 or may extend upwardly from a bottom of the first surface 1111 and have a height less than the second surface 1112. A plurality of third outer partition walls 1162 may be included. For example, as shown in FIG. 4, the two third outer partition walls 1162 may be spaced apart from each other in the longitudinal direction of the power control device 100 (e.g., the X-axis direction in FIG. 4). The third outer heat transfer element 1172 of the third heat transfer element 117 may be in into a space between the two third outer partition walls 1162. Both ends of the third outer partition wall 1162 may contact the other side of the third electrical element E3. In this regard, side surfaces of the third outer heat transfer element 1172 may be completely surrounded by the third electrical element E3 and the third outer partition wall 1162. A height of the third outer partition wall 1162 may be equal to or greater than the height of the third outer heat transfer element 1172.

The heat transfer element TM may effectively absorb heat emitted from the electrical element E and transfer it to the outside of the power control device 100. For example, the heat transfer element TM may transfer heat emitted from the electrical element E to the first and second surfaces 1111 and 1112 of the case 110 or to the partition walls W. Therefore, heat emitted from the electrical element E does not stay inside the power control device 100 including the internal space 111 but is distributed throughout the case 110 and quickly released to the outside of the power control device 100.

The heat transfer element TM may be applied to a region in contact with or adjacent to the electrical element E. For example, the heat transfer element TM may be applied to the seating region 118 together with an electrical element E. The heat transfer element TM applied to the seating region 118 may contact a plurality of surfaces of the electrical element E. For example, the heat transfer element TM may contact one or more of the plurality of side surfaces of the electrical element E and/or a bottom surface of the electrical element E. The heat transfer element TM applied to the seating region 118 may be aligned within the partition wall W. For example, the heat transfer element TM may be in contact with one or more surfaces of the partition wall W and also with (e.g., simultaneously with) one or more surfaces of the electrical element E. The heat transfer element TM may be applied between the partition wall W and the electrical element E. The height of the heat transfer element TM may be equal to or less than the height of the case 110 (e.g., the height of the second surface 1112). The height of the heat transfer element T) may be equal to or less than the height of the corresponding electrical element E. The heat transfer element TM may be in contact with the partition wall W and the electrical element E. The heat transfer element TM corresponding to one seating region 118 may contact a plurality of surfaces of the electrical element E corresponding to the seating region 118.

For example, a plurality of seating regions 118, electrical elements E, and heat transfer elements TM may be provided in the case 110, and the plurality of seating regions 118 may be spaced apart from each other.

For example, the heat transfer element TM may include a thermal conductive adhesive (TCA). The heat transfer element TM may include a binder having a thermal conductivity of about 1.5 W/m·K or more (e.g., one or more of epoxy, silicone, polyurethane, and other known binder materials) and a mixture of thermally conductive inorganic fillers (e.g., copper, silver, and other known inorganic fillers). The heat transfer element TM may be a two-component type heat transfer element in which a base material and a hardener are mixed separately, or a one-component type heat transfer element in which the base material and the hardener are mixed. The two-component heat transfer element TM may be applied around the seating region 118 where the electrical element E is seated by mixing a base material and a hardener by using a mixer or other mixing method. The one-component heat transfer element TM may be applied directly around the seating region 118 where the electrical element E is seated without an additional mixing process. After the heat transfer element TM is applied, the heat transfer element TM may be hardened by heat treatment, ultraviolet irradiation, or natural curing for a period of time.

The heat transfer element TM may include the first heat transfer element 113, the second heat transfer element 115, and the third heat transfer element 117.

The first heat transfer element 113 may be in the first seating region 1181 to correspond to the first electrical element E1. The first heat transfer element 113 may be accommodated between the first surface 1111, the second surface 1112, and the first partition wall 112 and may transfer and distribute heat generated from the first electrical element E1 to the first surface 1111 and the second surface 1112. The first heat transfer element 113 may contact one or more surfaces of the first electrical element E1. For example, the first heat transfer element 113 may contact both sides of the first electrical element E1 (e.g., both sides in the width direction of the power control device 100, for example, the Y-axis direction in FIG. 4). The first heat transfer element 113 may have a height equal to or less than that of the second surface 1112.

The first heat transfer element 113 may include the first inner heat transfer element 1131 and the first outer heat transfer element 1132.

The first inner heat transfer element 1131 may be accommodated in the first inner partition wall 1121 and may be in contact with one side of the first electrical element E1. The first outer heat transfer element 1132 may be accommodated in the two first outer partition walls 1122 and may be in contact with the other side of the first electrical element E1. The first inner heat transfer element 1131 may have a shape and size corresponding to an inner surface of the first inner partition wall 1121. The first inner heat transfer element 1131 may have a height H1, which may be equal to or less than an overall height of the first electrical element E1 and equal to or less than the height of the second surface 1112. The first inner heat transfer element 1131 may have a thickness T1a, which may be less than the thickness (or width) of the first electrical element E1 and greater than the thickness of the first partition wall 112. The first outer heat transfer element 1132 may have a height H1, which may be equal to or less than the overall height of the first electrical element E1 and equal to or less than the height of the second surface 1112. The first outer heat transfer element 1132 may have a thickness T1b, which may be less than the thickness of the first electrical element E1 and greater than the thickness of the first partition wall 112. The first inner heat transfer element 1131 and the first outer heat transfer element 1132 may be separated or spaced apart from each other.

The second heat transfer element 115 may be in the second seating region 1182 to correspond to the second electrical element E2. The second heat transfer element 115 may be accommodated between the first surface 1111, the second surface 1112, the third surface 1113, the groove 1114, and the third partition wall 116 and may transfer and distribute heat generated from the third electrical element E3 to the first surface 1111, the second surface 1112, the third surface 1113, and the groove 1114. For example, as shown in FIG. 4, a portion of the second heat transfer element 115 may be accommodated between the first surface 1111, the second surface 1112, and the third partition wall 116. Also, as shown in FIG. 7, a portion of the second heat transfer element 115 may be accommodated on the third surface 1113 and in the groove 1114. The second heat transfer element 115 has a shape corresponding to the second electrical element E2 and may surround at least a portion of the second electrical element E2. For example, if the second electrical element E2 is a cylindrical coil, the second heat transfer element 115 may have a concave shape having a curvature corresponding to an outer circumferential surface of the second electrical element E2. In this regard, as shown in FIG. 7, at least a portion of the circumference of the second electrical element E2 may be surrounded by the second heat transfer element 115. The second heat transfer element 115 may have a height equal to or less than the second surface 1112.

The second heat transfer element 115 may include the second inner heat transfer element 1151 and the second outer heat transfer element 1152.

The second inner heat transfer element 1151 lies on the third surface 1113 and may surround at least a portion of the second electrical element E2. For example, as shown in FIG. 7, the second inner heat transfer element 1151 has a concave shape corresponding to an outer circumferential surface of the cylindrical second electrical element E2, and the second electrical element E2 may be seated in the concave portion. Both sides (e.g., both sides in the Y-axis direction in FIG. 7) of the second inner heat transfer element 1151 may be in contact with the second inner partition wall 1141 and the second outer partition wall 1142, respectively. The side surface of the second inner heat transfer element 1151 adjacent to the second outer partition wall 1142 may contact the second surface 1112.

The second inner heat transfer element 1151 may surround at least a portion of the outer circumference of the second electrical element E2. For example, the second inner heat transfer element 1151 may surround about 30% to about 60% of the total length of the outer circumference of the second electrical element E2. If the ratio is less than about 30%, the second inner heat transfer element 1151 may not properly or sufficiently absorb heat generated from the second electrical element E2. If the ratio exceeds about 60%, on the contrary, heat may not be dissipated smoothly from the second electrical element E2, and the second electrical element E2 may be damaged. The second inner heat transfer element 1151 has a shape corresponding to the second electrical element E2, thereby stably supporting the second electrical element E2, and during the operation of the power control device 100, the second electrical element E2 may be prevented from being separated from the second seating region 1182 or the second heat transfer element 115.

At least one second outer heat transfer element 1152 may extend from the second inner heat transfer element 1151. For example, the second outer heat transfer element 1152 may extend downwardly from the second inner heat transfer element 1151 and may be inserted into (e.g., may extend into) the groove 1114. For example, as shown in FIG. 7, two second outer heat transfer elements 1152 may extend from a bottom surface of the second inner heat transfer element 1151 downwardly in the width direction (e.g., the −Z-axis direction in FIG. 7) of the power control device 100. One of the second outer heat transfer elements 1152 may extend downwardly from a side of the second inner heat transfer element 1151 that contacts the second surface 1112, and the other one second outer heat transfer element 1152 may extend downwardly from a side of the second inner heat transfer element 1151 that contacts the second inner partition wall 1141. In this regard, as shown in FIG. 7, the two second outer heat transfer elements 1152 may be spaced apart from each other and inserted into each groove 1114. Because the second outer heat transfer element 1152 is inserted into the groove 1114, the second heat transfer element 115 may be stably supported in the second seating region 1182, and the second heat transfer element 115 may not leave (or may not deviate) from the second seating region 1182 during the operation of the power control device 100. Also, because the second heat transfer element 115 contacts the case 110 at an enlarged area, heat emitted from the second electrical element E2 may be effectively and quickly dissipated.

The second inner heat transfer element 1151 and the second outer heat transfer element 1152 may be formed as one body (e.g., may be integrally formed). The second inner heat transfer element 1151 and the second outer heat transfer element 1152 may be formed as one piece without being separated or spaced apart from each other.

For example, as shown in FIG. 7, the second heat transfer element 115 may have a height H2. The height H2 is an overall height of the second heat transfer element 115 from a bottom of the second heat transfer element 115 (e.g., the bottom of the second outer heat transfer element 1152) to the top of the second heat transfer element 115 (e.g., the top of the second inner heat transfer element 1151). The second inner heat transfer element 1151 may have a height H2a, and the second outer heat transfer element 1152 may have a height H2b. The height H2a may be greater than the height H2b. The second inner heat transfer element 1151 may have a portion interposed between the second electrical element E2 and the third surface 1113, and the corresponding portion may include the thinnest (uninterrupted) portion of the second heat transfer element 115. For example, the corresponding portion may be a portion corresponding to D, which is the smallest distance between the second electrical element E2 and the third surface 1113. The distance D may be between about 5% and about 20% of the height H2a. If the ratio is less than about 5%, the heat absorption efficiency of the second heat transfer element 115 decreases and vibration of the second electrical element E2 may be directly transmitted to the third surface 1113, which may cause damage to the second electrical element E2 and the third surface 1113. If the ratio exceeds about 20%, the thickness of the second inner heat transfer element 1151 becomes excessively thick, which may impede smooth dissipation of heat from the second electrical element E2. The second heat transfer element 115 may have a width T2. The width T2 is a total width of the second heat transfer element 115, which denotes the largest width of the second heat transfer element 115 in the width direction of the power control device 100 (e.g., the Y-axis direction in FIG. 7). The width T2 may be greater than a width of the second heat transfer element 115.

The third heat transfer element 117 may be in the third seating region 1183 to correspond to the third electrical element E3. The third heat transfer element 117 may be accommodated within the first surface 1111, the second surface 1112, and the third partition wall 116 and may transfer and distribute heat generated from the third electrical element E3 to the first surface 1111 and the second surface 1112. The third heat transfer element 117 may contact one or more surfaces of the third electrical element E3. For example, the third heat transfer element 117 may contact both sides of the third electrical element E3 (e.g., both sides in the width direction of the power control device 100, for example, the Y-axis direction in FIG. 4). The third heat transfer element 117 may have a height equal to or less than the second surface 1112.

The third heat transfer element 117 may include the third inner heat transfer element 1171 and the third outer heat transfer element 1172.

The third inner heat transfer element 1171 may be accommodated in the third inner partition wall 1161 and may be in contact with one side of the third electrical element E3. The third outer heat transfer element 1172 may be accommodated within the two third outer partition walls 1162 and the second surface 1112 and may be in contact with the other side surface of the first electrical element E1. The third inner heat transfer element 1171 may have a shape and size corresponding to an inner surface of the third inner partition wall 1161. The third inner heat transfer element 1171 may have a height H3, which may be equal to or less than an overall height of the third electrical element E3 and equal to or less than the height of the second surface 1112. The third inner heat transfer element 1171 may have a thickness T3a, which may be less than the thickness of the third electrical element E3 and greater than the thickness of the third partition wall 116. The third outer heat transfer element 1172 may have a height H3, which may be equal to or less than the overall height of the third electrical element E3 and equal to or less than the height of the second surface 1112. The third outer heat transfer element 1172 may have a thickness T3b, which may be less than the thickness of the third electrical element E3 and greater than the thickness of the third partition wall 116. The third inner heat transfer element 1171 and the third outer heat transfer element 1172 may be separated or spaced apart from each other.

One or more battery modules 200 are included in the battery pack 10 and may be electrically/physically connected to the power control device 100. The battery module 200 may include a plurality of battery cells electrically connected to each other through cell tabs or the like. If there are a plurality of battery modules 200, the plurality of battery modules 200 may be electrically connected to each other through bus bars. Although the embodiment illustrated in FIG. 2 includes twelve battery modules 200, the number of battery modules 200 is not limited thereto and may vary depending on the specifications of the battery pack 10. The battery module 200 may be accommodated inside the housing 300. The battery cells included in the battery module 200 may be one or more of cylindrical, prismatic, and pouch type battery cells.

The housing 300 may hold (or accommodate) and support other components of battery pack 10 (e.g., power control device 100, the battery module 200, and the controller 400). The housing 300 has an internal space, and the power control device 100, the battery module 200, and the controller 400 may be included in (e.g., may be accommodated in) the internal space. The housing 300 may protect other components of the battery pack 10 from external impact and foreign substances.

The housing 300 may include attachable and detachable parts different from each other. For example, the housing 300 may include a case in which a bottom and a plurality of side walls extending along an edge of the bottom are integrally formed and a cover that is attachable and detachable to and from the case. The housing 300 may be attachably and detachably installed in other applications, such as the vehicle 1. The controller 400 may detect the current state of the battery pack 10 and

control charge/discharge and supply power of the battery pack 10 accordingly. The controller 400 is mounted within the housing 300 and may be electrically connected to the power control device 100 and the battery module 200. For example, the controller 400 may adjust a voltage by balancing the voltage of each battery cell included in the battery module 200 and control the battery cells to prevent overload. Also, the controller 400 may measure a temperature and current of the battery cell to prevent over- and under-current of the battery cell and manage the temperature of the battery cell. The controller 400 may detect a current, voltage, and temperature of the battery cell to predict the state of charge (SOC) and prevent overcharge and over discharge of the battery module.

The controller 400 may control the power supplied to the application by controlling the power control device 100. For example, the controller 400 may allow a current supplied from the battery module 200 to be supplied to a load, such as a motor or inverter of the vehicle 1, through the power control device 100. If an overcurrent flows in the battery module 200 or an electrical leakage or short circuit occurs, the controller 400 may cut off the current flowing through the power control device 100. For example, the controller 400 may cut off a current supplied to coils of a plus main relay and a minus main relay as an electrical element E included in the power control device 100 to cut off a current supplied from the power control device 100 to the application.

In the battery pack according to embodiments of the present disclosure, heat transfer elements absorb heat generated from electrical elements of a power control device and effectively and quickly discharges the heat to the outside of the case, thereby improving the reliability and durability of the electrical element and the power control device including the electrical element and the entire battery pack.

In the battery pack according to embodiments of the present disclosure, partition walls regulate the shape, size, region, and application region of the heat transfer element so that the heat transfer element is not applied to regions other than the seating region or the shape and size are not uneven.

In the battery pack according to embodiments of the present disclosure, the heat transfer element absorbs heat generated from the electrical element and releases the heat to one or more of the first, second, and third surfaces, grooves, and partition walls of the case, thereby preventing overheating of the electrical element.

However, the aspects and features of the present disclosure are not limited to the above-mentioned aspects and features, and other aspects and features not mentioned may be clearly understood by those skilled in the art from the description of the present disclosure and the following claims.

While the present disclosure has been described with reference to embodiments that are shown in the drawings, these are merely examples. It will be understood by those of ordinary skill in the art that various changes in form and details may be made therein without departing from the spirit and scope of the present disclosure. Accordingly, the technical scope of the present disclosure is defined by the appended claims and their equivalents.

It should be understood that the embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the present disclosure as defined by the following claims and their equivalents.

What is claimed is:

1. A battery pack comprising:
a plurality of battery modules; and
a power control device configured to control power supplied by the plurality of battery modules, the power control device comprising:
a case comprising a partition wall defining a seating region;
an electrical element within the case; and
a heat transfer element in contact with or applied around the electrical element.

2. The battery pack as claimed in claim 1, wherein the electrical element and the heat transfer element are in the seating region.

3. The battery pack as claimed in claim 1, wherein the heat transfer element is in contact with the partition wall and the electrical element.

4. The battery pack as claimed in claim 1, wherein the heat transfer element is in contact with a plurality of surfaces of the electrical element.

5. The battery pack as claimed in claim 1, wherein the seating region, the electrical element, and the heat transfer element are each provided in plurality in the case, and
wherein the plurality of seating regions are spaced apart from each other.

6. The battery pack as claimed in claim 1, wherein the case has:
a first surface forming a bottom surface of the case; and
a second surface extending along an edge of the first surface,
wherein the partition wall extends from at least one of the first surface and the second surface, and
wherein the seating region is defined by the first surface, the second surface, and the partition wall.

7. The battery pack as claimed in claim 6, wherein the partition wall comprises:
an inner partition wall extending from the first surface and spaced apart from the second surface; and
an outer partition wall extending from the second surface toward the inner partition wall.

8. The battery pack as claimed in claim 7, wherein the heat transfer element is applied within the inner partition wall and in contact with the inner partition wall and one surface of the electrical element, and
wherein the heat transfer element is applied within the outer partition wall and in contact with the outer partition wall, the second surface, and other surface of the electrical element.

9. The battery pack as claimed in claim 7, wherein the outer partition wall comprises two outer partition walls spaced apart from each other and extending from the second surface, and
wherein the heat transfer element is applied between the two outer partition walls.

10. The battery pack as claimed in claim 6, wherein the seating region, the electrical element, the heat transfer element, and the partition wall comprise a plurality of seating regions, electrical elements, heat transfer elements, and partition walls, respectively.

11. The battery pack as claimed in claim 10, wherein the seating region comprises a first seating region, a second seating region, and a third seating region spaced apart from each other,
wherein the electrical element comprises a first electrical element, a second electrical element, and a third electrical element corresponding to the first seating region, the second seating region, and the third seating region, respectively,
wherein the heat transfer element comprises a first heat transfer element, a second heat transfer element, and a third heat transfer element corresponding to the first seating region, the second seating region, and the third seating region, respectively, and
wherein the partition wall comprises a first partition wall, a second partition wall, and a third partition wall corresponding to the first seating region, the second seating region, and the third seating region, respectively.

12. The battery pack as claimed in claim 11, wherein the first partition wall comprises:
a first inner partition wall extending upwardly from the first surface and having both ends extending in a longitudinal direction toward the second surface; and
two first outer partition walls extending from the second surface toward the first inner partition wall and being spaced apart from each other,
wherein the first electrical element is at a central portion of the first seating region between the first inner partition wall and the first outer partition wall.

13. The battery pack as claimed in claim 12, wherein the first heat transfer element comprises:
a first inner heat transfer element accommodated in the first inner partition wall and in contact with one surface of the first electrical element; and
a first outer heat transfer element separated from the first inner heat transfer element, accommodated between two first outer partition walls, and in contact with another surface of the first electrical element.

14. The battery pack as claimed in claim 11, wherein the second partition wall comprises:
a second inner partition wall extending upwardly from the first surface, both ends of which extend in a longitudinal direction toward the second surface; and
two second outer partition walls extending from the second surface toward the second inner partition wall and spaced apart from each other,
wherein the second electrical element is at a central portion of the second seating region between the second inner partition wall and the second outer partition wall.

15. The battery pack as claimed in claim 14, wherein the second electrical element has an outer circumferential surface that is at least partially curved, and
wherein a portion of the second heat transfer element has a concave shape corresponding to the outer circumferential surface of the second electrical element.

16. The battery pack as claimed in claim 15, wherein the case has:
a third surface protruding upwardly from the first surface; and
a groove around the third surface,
wherein the third surface and the groove each correspond to the second seating region, and
wherein the second heat transfer element comprises:
a second inner heat transfer element between the third surface and the second electrical element; and
a second outer heat transfer element extending from the second inner heat transfer element and extending into the groove.

17. The battery pack as claimed in claim 11, wherein the third partition wall comprises:
a third inner partition wall extending upwardly from the first surface, both ends of which extend in a longitudinal direction toward the second surface; and
two third outer partition walls extending from the second surface toward the third inner partition wall and spaced apart from each other,
wherein the third electrical element is at a central portion of the third seating region between the third inner partition wall and the third outer partition wall.

18. The battery pack as claimed in claim 17, wherein the third heat transfer element comprises:
a third inner heat transfer element accommodated in the third inner partition wall and in contact with one surface of the third electrical element; and
a third outer heat transfer element separated from the third inner heat transfer element, accommodated between two third outer partition walls, and in contact with another surface of the third electrical element.

19. The battery pack as claimed in claim 11, wherein the first electrical element comprises a minus main relay, the second electrical element comprises a fuse, and the third electrical element comprises a plus main relay.

20. The battery pack as claimed in claim 1, wherein the heat transfer element comprises a binder and a thermally conductive inorganic filler mixture.
